(19) United States
(12) Patent Application Publication
(10) Pub. No.: US 2011/0254885 A1
(43) Pub. Date: Oct. 20, 2011

(54) DATA RECORDING METHOD FOR LONG-TERM READING OF SAID DATA

(76) Inventors: Thierry Prigent, Sainte-Helene (FR); Eric Prigent, Montrouge (FR); Karine Van Heumen, Marseille (FR)

(21) Appl. No.: 12/742,027

(22) PCT Filed: Nov. 10, 2008
(86) PCT No.: PCT/FR2008/051984

§ 371 Date: Feb. 14, 2011

(30) Foreign Application Priority Data
Nov. 9, 2007 (FR) 07/58910

(51) Int. Cl. G11C 99/00

(52) U.S. Cl. 346/146

(57) ABSTRACT

According to this method, there is recorded on the same recording medium (1):
a) an encoded recording (A) of the data allowing them to be read automatically,
b) a recording (B), intended for intuitive visual reading, of the knowledge necessary for using means for decoding (MD) the data in order to read them automatically.

The present invention relates to a data recording method for the automatic long-term reading of those data. The present invention also relates to a data recording medium obtained by using that method.

From the outset, man has transmitted his knowledge to his contemporaries, or future generations, by various means and particularly in writing and in images which are fixed to media of different materials, such as, for example, stone, wood, terracotta, animal skins, fabrics or paper. When stored under favourable archiving conditions, those media have demonstrated remarkable durability. In this manner, ancient documents which have endured for several hundreds or several thousands of years have reached us in a state allowing them to be decrypted by simple visual examination.

Conventional techniques for transmitting information have been supplemented since the relatively recent advent of data processing by other techniques involving the establishment and transmission of digitised data constituting an encoded translation of data, for example, of the “image” or “text” type, that translation not being directly readable by a human-being. Establishing that translation and recording it on a medium capable of fixing it involve electronic items of hardware and items of software, as does the reconstitution from that medium of visually readable images and texts. In the case of audiovisual programmes, the reproduction of sound is an additional aspect.

In this manner, the reconstitution or reproduction uses a chain of means which substantially comprises, in addition to the medium storing the data, a reader for those data, a standardised interface for communication with a data processing infrastructure, a compatible operating system, application software and a device for displaying the data reconstituted by the software.

Although this chain is complex, it affords the very substantial advantages which data processing of data brings about, particularly with regard to classification and indexing of information, logical grouping of the information by homogeneous entities (dossier, project or subject, etc.), automation of access to the information and therefore distribution of the information.

However, it is only necessary for one of the links of the chain to be defective or unavailable for access to the information to become impossible. There are a large number of causes of failures or unavailability of those links.

Firstly, with regard to the medium on which the data are recorded in digitised form, commonly constituted by a physical storage layer carried by a mechanical base in the form of a sheet, strip or disc, for example, that base having a relatively fine thickness may become damaged over time, as can the storage layer which loses recordings of information owing to local or partial destruction of the layer, reduction of its storage properties over time (which particularly affects magnetic layers) or random deletion (which affects electronic storage devices “in the solid state” struck by cosmic rays). Finally, the medium is generally protected in a container whose design and functionalities may be non-standardised and therefore have reduced or non-existent interchangeability.

The reader for the data recorded on such a medium comprises a mechanical precision component, an electronic unit and internal activation software (or firmware) which must remain compatible with the format of the data written to the medium. The mechanical component is subject to wear and the electronic unit may be affected by failures of components which are difficult to replace when they become obsolete.

The standardised communication interface is also affected by the rapid development of interfacing and by frequent changes in communication standards.

Finally and above all, the various pieces of software in question (internal activation software of the reader, software of the communication interface, drivers which form part of the operating system, application software) are subject to rapid obsolescence which results from the constant progress of data processing. They are often replaced by new versions which cause the old versions to disappear, or even by entirely rewritten software.

The pieces of software which lose their usefulness in this manner tend to disappear from libraries of software. The data processing systems which use those pieces of software themselves become unusable.

Current obsolescence of data processing software and hardware is so rapid that it has been possible to assess the survival term of the data recorded by the method described above as being of five years on average. The long-term usefulness of archives which are constituted by data stored in this manner is therefore very low or zero. There are currently substantially two responses to this state of affairs.

According to the first of those responses, the data are regularly recopied onto a more recent medium, which further necessitates most often transcoding of the data into formats which are compatible with the data reading software currently available at the time of transcoding. Those operations have the disadvantage of being extremely troublesome and therefore are unattractive in the long term, particularly since the volume of data to be transcribed will do nothing but increase with time. In this manner, for some high-volume archives, the transcoding time will exceed the useful life of the new encoding obtained. This results in losses of data.

According to the second theoretically possible response, it is possible to attempt to recover data carried by an old medium for computerised data which have been recorded with hardware and software which have vanished by finding, restoring or reconstructing the hardware and software. When it is attempted to apply this procedure to a relatively recent data processing medium, such as an 8″ floppy disk in use in the 1980s, for example, it quickly becomes apparent that the total effort required is such that the procedure quickly appears to become unattractive. It will be even less attractive for an archivist of the future who will be even more remote from the sources of information which currently could allow the reconstruction work envisaged above.

There may also not be the motivation necessary for undertaking work as substantial as this because the interest in the data content of the medium a priori cannot most often be assessed optionally to justify the effort to be taken owing to the inaccessibility of the content.

The present invention specifically relates to the provision of a data recording method which allows construction of a data recording medium which is capable of constituting an automatically usable archive, even in the very long term, in spite of the disappearance of the data processing means, hardware and/or software which were available at the time of its creation.

The present invention also relates to the construction of such a medium which is capable of bringing about the storage of all types of data, which may be digital or analogue in origin, and all types of recording, in particular of audiovisual programmes.

This object of the invention and others which will become clear from reading the following description are achieved with a data recording method for the automatic long-term reading of the data which is remarkable in that there is recorded on the same recording medium:

a) an encoded recording (A) of the data allowing them to be read automatically,
b) a recording (B), intended for intuitive visual reading, of the knowledge necessary for using means for decoding (MD) the data in order to read them automatically.

As will be seen below in greater detail, it is possible to constitute archives which can be used readily and automatically in the future by way of hardware and software means which exist at the time of use when even that use would occur a very long time after the creation of the archive. It is no longer necessary, in order to read the archive, to use heavy and expensive solutions involving the recreation or reactivation, when it is possible, of software means which existed when the archive was created or the transcoding of the data to be archived, which is repeated periodically over time.

As will also be seen in greater detail below, the presence on the recording medium, or archive, of visual reading data allows information relating to the content of the archive to be made immediately accessible. It is possible to rapidly assess the interest of that content before carrying out the operations intended to bring about automatic reading of the content. The corresponding expenditure is undertaken in full knowledge of the facts. It is also possible to rapidly estimate the storage state of the recording medium without having to read the recordings.

According to other features of the present invention:
the intuitive reading is brought about by the juxtaposition, on the recording medium, of visual reading signs and the associated codes thereof,
the codes are intended for automatic reading by optical means,
the code associated with the sign is constituted by at least one elementary field of a recording surface of the medium having an optical characteristic specific to the sign,
the code associated with the sign is constituted by combining a plurality of elementary fields of the medium, for which a combination of the optical characteristics is specific to the sign,
the characteristic is selected from the group formed by: a shape, colour and/or optical density of at least one field of the recording medium,
the sign associated with each of the codes is adjacent to the code,
in a variant, the sign associated with each of the codes is superimposed on the code,
the recording medium is formatted in consecutive sectors,
in an adaptation of the method to recording on the medium documentary objects of different types, the sectors are configured in accordance with the type of each object,
for each object recorded, a directory of the sectors on which it is recorded is further recorded,
this directory is intended to be read visually,
this directory is further intended to be read automatically,
there is further recorded, for each documentary object recorded, a visually readable nomenclature of the information to be taken into consideration in order to prepare automatic reading of the recording,
the nomenclature includes the rules of the encoding of signs,
the nomenclature comprises a schematic illustration of the distribution of the data relating to at least one of the objects on a standard sector of the medium,
the nomenclature comprises pictograms in order to assist visual recognition of various portions of a recording of an object comprising recordings of different types,
there is further recorded on the medium a visually readable preview of characteristics of the data intended for automatic reading, which preview is capable of allowing preselection of a portion of interest of the recording (A),
in a variant, the preview is integrated in the directory.

The present invention also relates to the data recording medium obtained by using the method according to the invention, the medium being remarkable in that it comprises:

a) an encoded recording (A) of the data allowing them to be read automatically,
b) a recording (B), intended for intuitive visual reading, of the knowledge necessary for using means for decoding (MD) the data in order to read them automatically.

According to other features of that medium:
the recordings (A) and (B) are carried by a layer of an optically readable recording material,
the medium is in the form of a strip-like product,
in a variant, the medium is in the form of a sheet-like product,
when it is in the form of a strip-like product, the medium is formatted in consecutive sectors along the longitudinal axis of the strip,
it comprises, at least at one end of the strip, visually readable sectors which are assigned to recording characteristics of the content of the automatically readable encoded data, those encoded data being recorded on sectors of the strip associated with the visually readable sectors,
the visually readable sectors comprise sectors which are assigned to recording a nomenclature of the information to be taken into consideration in order to prepare automatic reading of the encoded recording (A) of the data,
the visually readable sectors are repeated at the other end of the strip,
when it comprises recordings of a plurality of documentary objects of different types, the various successive lengths of the strip which carry those recordings are formatted in sectors having dimensions adapted to the type of the corresponding recording,
the medium comprises recordings of data intended to be used during operations for restoring/repairing that medium.

Other features and advantages of the present invention will be appreciated from a reading of the following description and examination of the appended drawings, in which:

FIG. 1 illustrates a portion of a specific embodiment of a recording medium resulting from the recording method according to the invention being used,

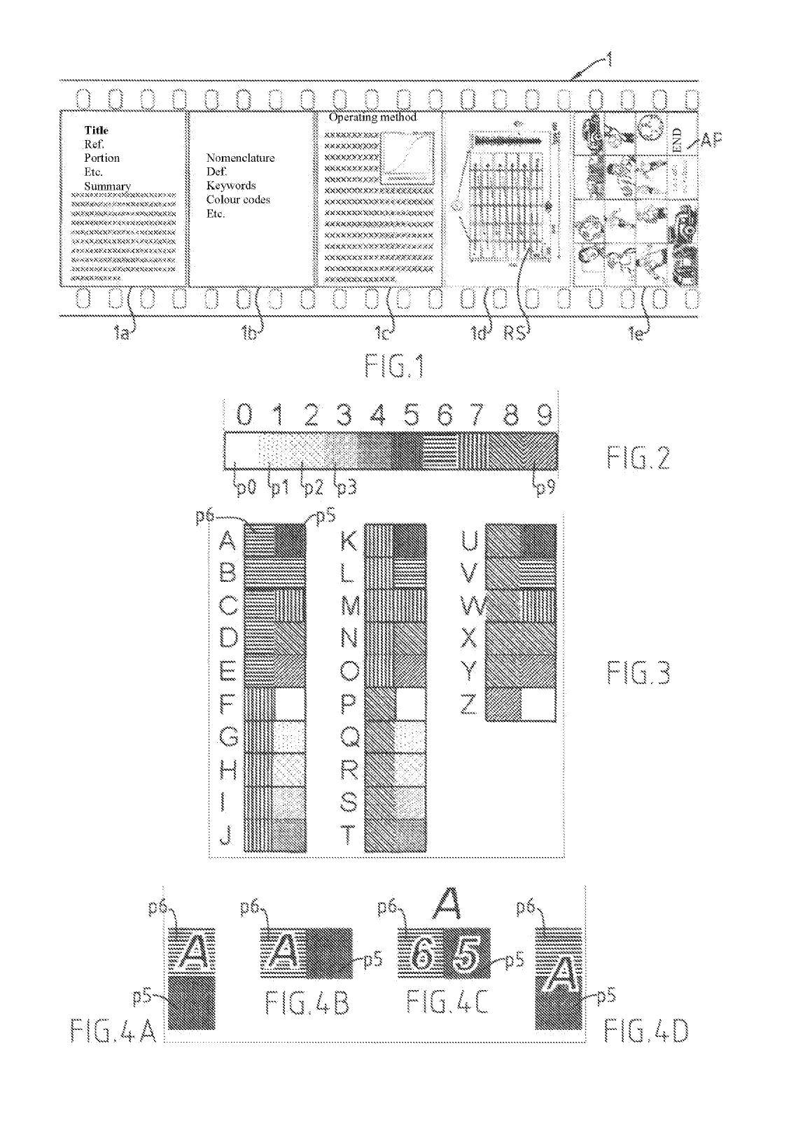

FIGS. 2, 3 and 4A to 4D illustrate a method of encoding signs which is suitable for automatic reading of those signs by optical media and which can be used in the data recording method according to the invention,

FIG. 5 illustrates a field or sector of the recording medium of FIG. 1, carrying an image which allows the format of the recording of a documentary object archived on that medium to be determined by intuitive human reading,

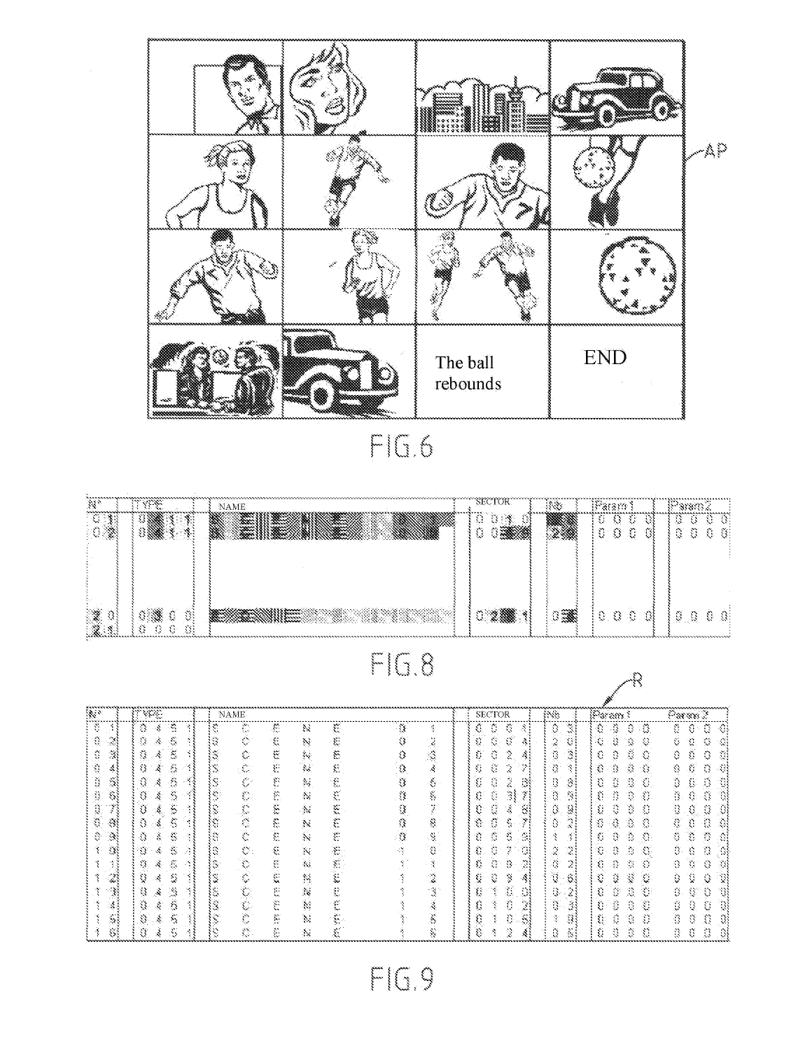

FIG. 6 illustrates another sector of that medium carrying an image which constitutes a preview, intended for visual human reading, of the content of that recording,

FIG. 7 illustrates a standard sector of the medium recorded in accordance with the format illustrated in FIG. 5,

FIG. 8 illustrates a directory of the characteristics and the recording positions of successive portions of documentary objects archived on this medium, this directory being configured according to the invention to be suitable for human visual reading as well as automatic reading and

FIG. 9 illustrates a directory of the same type as that illustrated in FIG. 8 associated with the recording, a preview of which is illustrated in FIG. 6.

As set out above, an object of the recording method according to the present invention is to allow in particular intuitive visual reading of the knowledge necessary for reconstructing means for automatically reading data which are archived by this method on a recording medium. The medium must be capable of fixing signs or images which are visible to a human-being. There are known a number of media of this type, such as photosensitive films or papers used in photography or cinematography, image media formed by inkjet or by the xerographic method, media having photosensitive layers for thermographic development, development by sublimation, etc. There could be envisaged other recording media, such as, for example, a suitably engraved stainless steel strip, so long as they are capable of retaining information visible to a human-being, by direct observation or by means of an image magnification device.

There will preferably be selected a recording medium in the form of a thin film, sheet or strip, so as to be able to store great quantities of information in a small space.

Similarly, there will advantageously be chosen a recording material which is non-erasable and has a long useful life, the durability being an essential feature of this material in the application of archiving data which can be recovered in the very long term, which is more particularly, though not exclusively, intended by the present invention.

Reference is made to FIG. 1 of the appended drawings, which illustrates, purely by way of non-limiting example, a portion of a recording medium according to the invention in accordance with a specific embodiment in the form of a laterally perforated strip 1 of photographic or cinematographic film.

Such a medium is equally suitable for recording data which are intended for visual reading by a human-being and recording data which are intended for automatic reading by means of an image analysis device (commonly referred to as a scanner), for example, and associated reading software.

It will further be observed that the durability thereof is remarkable, photographic recordings which are almost 200 years old currently being known. Studies of accelerated ageing in an oven have demonstrated that, over several centuries, the deterioration of monochrome photographic images is negligible, and that of colour images is only in the order of 10%. There are further known means for restoring images by compensating for that deterioration and even means for repairing any damage of mechanical origin suffered by the sensitive layer or the carrier thereof. Integrating a sensitometric chart which ages at the same time as the fields of the medium which carry data in the medium according to the invention constitutes a means allowing the compensation to be carried out to be adjusted. In the case of animated images, the repair of images may be carried out by exploiting redundancies between images.

Recording data on such a support is carried out by exposing the photosensitive layers thereof to images of the data to be recorded then developing and fixing the recorded latent images. That exposure can be brought about by conventional means of image projection, for example, or by scanning in a printer, advantageously at high-resolution, controlled by a digital file which constitutes a “virtual image” of the whole of the information to be transferred to the photographic film strip. For the present invention, this last solution will be advantageously preferred because the involvement of a digital file is capable of facilitating the operations for assembling composite data to be carried out before exposure.

Processing that virtual image uses software for preparing the data to be recorded. Those data may correspond to very different documentary objects: texts, images, drawings, plans, graphs, signals, raw data, etc., which may be constituted by collections of sub-objects. For example, a text may be constituted by pages illustrated with drawings, graphs, images, etc. It constitutes a heterogeneous object composed of a plurality of levels of sub-objects. At the main level, there is the title of the text, the name of the author, a table of contents, a summary, etc. . . . . Similarly, at the level of the chapters, there is a conventional series of levels: Chapter 1, 2 . . . N, each chapter itself being subdivided into pages, each comprising text, drawings, images, etc. All these objects and sub-objects may be adjacent on the final film strip, on which those objects are archived.

Similarly, archiving a cinematographic programme or television programme will mainly be constituted by “image” type objects which may be associated with text and/or drawings which place the work into its context.

The preparation software allows ordering of the objects and sub-objects to be archived on the strip. They are further subjected to encoding by type (control objects, object of the type “image”, “sound”, “signal”, “text”, “multimedia”°, . . . as will be seen in the remainder of the present description.

The digital file obtained using this software allows control of the exposure of a blank photographic film strip to the images of the various objects gathered in this file. As has been seen above, a commercially available digitally controlled printer will be used, preferably a high resolution printer.

After development of the strip which has been exposed in this manner, the archive is constituted. Subsequently, it is processed so as to be able to withstand the effects of time.

According to the present invention, this archive is configured in such a manner that its content can be, even over a very long period of time, assessed by a human-being by simple visual examination. It is also configured so that human-beings can reconstruct means allowing automatic reading of a portion of interest PI of the archive that is preselected by visual examination, or even of the entire archive if necessary.

Such reading involves the use of a scanner and reading software using data which are provided during reading of the strip by the scanner. That scanner and software constitute means MD for decoding and therefore reading those data. In the long term, the software will very probably have to be reconstructed by an archivist of the future in accordance with the characteristics and capacities of the computers then available. An object of the present invention is precisely to provide him, in order to do this, with all the necessary information recorded on the strip itself and able to be interpreted by simple visual reading.

Again, with reference to FIG. 1 of the appended drawings, it appears that the portion of film strip 1 according to the invention illustrated in the Figure is “formatted” in consecutive rectangular fields 1a, 1b, 1c . . . 1e . . . , or “sectors”, by analogy with the terminology used to describe the organisation of data processing magnetic discs. Those sectors are of fixed size on that strip portion. Purely by way of non-limiting example, on a conventional cinematographic film strip which is 35 mm wide, each sector occupies a film field corresponding to four consecutive perforations in accordance with the length of the film, as illustrated. It will be appreciated that those perforations advantageously allow reference, by means of a counter, to the strip in order to go directly to this or that sector of interest.

With a printer which is currently available, it is possible to record each sector, for example, with a resolution of 2048×1536 pixels.

Such a format is very well-suited to archiving objects of the “text” type, drawings, photos or cinematographic sequences. In the case of objects of the video type, sound recordings or of the multimedia type (in the data processing sense of this word), multi-track formatting of sectors of smaller size can advantageously be adopted.

The size of the sectors may vary along the strip in order to adapt to the size of the objects to be recorded. This is a feature of the present invention whose full advantage will be disclosed in the remainder of the present description.

The portion of the strip illustrated in FIG. 1 is placed at the leading portion thereof, immediately after one or two windings of a mechanically protective leading portion of the strip, it being wound conventionally on a spool. In this leading portion, there is advantageously positioned according to the invention a recording B of the information, whose purely visual reading will afford an archivist or archaeologist of the future access to the information written on that strip, in particular using automatic reading means. That leading portion may also advantageously contain a preview of the content of the strip, as will be seen below. In this manner, the archivist or archaeologist learns about the content without having to unroll the strip.

That leading portion is advantageously repeated at the other end of the strip in order to avoid needlessly having to unroll it. That portion may further also be repeated periodically along the strip.

Those leading portions may be omitted, completely or partially, or increased as necessary. The sectors are advantageously of a format of the “microfilm” type in order to facilitate reading thereof by optical projection.

There is between those two leading portions a length of strip carrying a recording A of the content itself of the archive, which is encoded and formatted according to the present invention so as to be suitable for automatic reading by means of hardware means which are available at the time of reading and software means which are reconstituted by the archivist using information contained in the leading portions. That automatic reading avoids “human” reading of the content of the archive, which is possible but long and tedious.

This content is distributed over consecutive numbered sectors 1i (i from 1 to N) of the strip and each “object” of this content is indexed in relation to the numbers of the sectors which carry it.

The leading portion of the strip 1, which is entirely intended for human reading, may comprise, as illustrated in FIG. 1, a sector 1a, in which there are written the title of the work recorded on the strip, a classification code, a summary of the work, etc. . . . , and any other bibliographic data relating to the work in question.

The following sector 1b may be assigned to a nomenclature of data relating to the technical characteristics of the recording carried by the strip. Those data relate particularly to the encoding, according to the present invention, to be used to carry out automatic reading of characters, figures, letters or the like, recorded on the strip. That encoding, intended for intuitive reading according to the invention, will be explained below in conjunction with FIGS. 2 to 4 and 8 and 9 of the appended drawings.

That nomenclature may be enhanced by other useful data: definitions, key words, etc. . . .

The sector 1c contains a “method for use” which provides all the information useful for correct interpretation of the data or the documents recorded on the strip. Some rules, which may be implicit or explicit when the documents are archived, may become lost over time.

By way of example, it is possible to refer to the implicit rules which currently govern the display or reproduction of digitised images which are constituted by matrixes of pixels. If the reproduction screen used is a data processing screen, with LCD matrixes, for example, the pixels are of square shape and “gamma” (coefficient of the exponential function connecting the numerical values of the pixels to the light intensity emitted by each pixel of the screen) is unitary. If the screen used is a cathode ray tube, the pixels are rectangular and have gamma of 2.2. Such information (including the definition of the parameter gamma) which is implicit today may become lost with time. Therefore, it is advantageously included in the method for use to give an archivist of the future the means to bring about correct reproduction of the image in question.

The sector 1d contains a schematic illustration RS of the physical distribution of the information recorded in a sector of the “content” portion of the strip. The schematic illustration RS is specific to the type of the object recorded. It is configured according to the invention so that an archivist of the future can, by intuitively reading the schematic illustration, locate the information necessary to him to reconstruct software means allowing automatic reading of the content of the strip. The schematic illustration RS will be described in greater detail in conjunction with FIGS. 5 and 7, illustrating a specific embodiment of the recording medium according to the present invention.

The sector 1e contains a preview AP of the content of the object recorded on the strip. That preview is also intended to be read by humans. It assists, in conjunction with the other information contained in the leading portion of the strip, the archivist or archaeologist of the future to select a portion of interest PI on the strip. That selection allows a limitation of the effort for reconstructing the reading software to the effort necessary to consult that portion of interest PI. Such a preview will be described in greater detail below in conjunction with FIG. 6 which illustrates, with the FIGS. 5, 7 and 9, a specific embodiment of the medium according to the present invention.

It is clear that the sectors 1a to 1e as described above, intended only for visual reading, may or may not be present on the strip, as necessary. Furthermore, the purely textual portions intended for visual reading in those sectors may be doubled by the automatic reading means according to the present invention, which will be described in the remainder of the present description. In this manner, the user has a choice between two reading modes. He may choose one or the other, for example, in accordance with the storage state thereof.

As has been set out above, the present invention relates to the creation of an archive which can be exploited in the long term and which combines the advantages of archives intended for visual reading, in particular in terms of accessibility to the data recorded, and archives intended for automatic reading in terms of classification, indexing, logical grouping of the information by homogeneous entities and automation of access to the information.

In order to solve the problem posed by the introduction of that double-reading, the present invention proposes a language of communication between the three entities constituted by the recording medium (the archive), a human-being (the archivist) and hardware and software means for automatic reading (an “intelligent” scanner).

According to a feature of the present invention, this language is intended for “intuitive” visual reading. Such reading is intuitive in that, for a human-being of normal intelligence, the juxtaposition or topological coupling which exists on the recording medium between a code intended for visual reading, such as a typographical character, figure or letter, for example, and its translation into a code intended for automatic reading by suitable hardware and software means demonstrates the bond of meaning which connects them. FIGS. 2 to 4 illustrate the basic features of this language.

FIG. 2 illustrates a set of elementary fields or “pads” p0, p1, p2 . . . p9 which are adjacent to decimal FIGS. 0, 1, 2, . . . 9, respectively.

Each of the pads p0, p1, p2 . . . p9 has an optical characteristic which is different from those of the other pads so that there is biunivocal correspondence between each of the figures and the associated pad pi (i being from 0 to 9).

Those pads may be of square shape, as illustrated, or another shape, rectangular, circular, etc.

The specific optical characteristic of the field surrounded by the outer contour of the pad may be very diverse. It may be the shape of this field or a graphic contained therein or advantageously its colour and/or its optical density, for example. It is simply necessary for that optical characteristic to be specific to the adjacent decimal figure and to be unambiguously distinguished from those of the other figures.

Naturally, it would be possible to select encoding with a base other than decimal, for example, hexadecimal.

The bar of pads and figures illustrated in FIG. 2 is advantageously incorporated in the nomenclature included in sector 1b of the leading portion of the strip. The visible coupling of each pad and a specific adjacent figure should in theory lead the archivist who discovers the bar to deduce therefrom identity of significance between the pad and the corresponding figure simply by using his intuition.

That identity of significance may be made even more evident by the figures and the corresponding pads being superimposed in the bar.

Once he has intuitively understood that each pad encountered on the strip represents the associated figure in the bar, it becomes obvious to the archivist that the means for reading the strip (scanner and software for interpreting the output signal of the scanner) must be programmed so as to translate that code into a non-encoded state.

That encoding extends to the letters of the alphabet, for example, Latin, in order to allow optical encoding of a text which comprises both figures and letters, or other useful signs in typography. Only the encoding of letters will be described below in order not to unnecessarily complicate this description. It is clear that the principles for encoding signs set out in this description may be readily extended to any sign other than those described and in particular to those of alphabets other than Latin, or signs used in non-alphabetic languages such as, for example, Chinese.

FIG. 3 illustrates a directory of the optical codes which it is possible to associate with each letter of the Latin alphabet in accordance with an embodiment of this directory given merely by way of example. Such a directory may be recorded, similarly to the one relating to decimal figures, in the nomenclature recorded in the sector 1b.

It appears in this Figure that each letter is adjacent to a specific pair of the pads p0 to p9. The reason for this is that, in order to encode those letters, the pads which correspond to their numerical codes in ASCII decimal have been selected. In this manner, for example, the letter A is encoded by a pair of pads p6, p5 corresponding to the numerical code 65 assigned to this letter in ASCII. The other letters are encoded similarly.

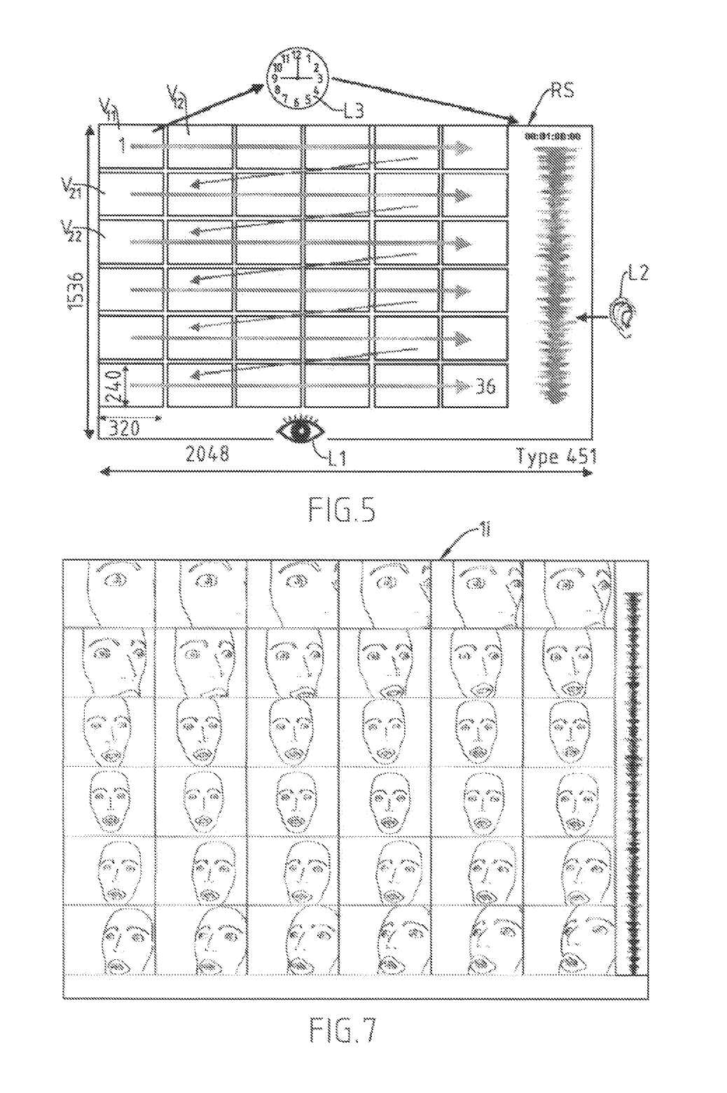

FIG. 4 illustrates other configurations of pairs of pads which can be used to encode letters, the letter A being selected by way of example. In FIG. 4A, the pads are vertically juxtaposed and the letter A is printed on the pad p6. In FIG. 4B, the pads are juxtaposed horizontally and the letter A is also printed on the pad p6. In FIG. 4C, the FIGS. 6 and 5 are printed on the pads p6 and p5 which are horizontally juxtaposed. In FIG. 4D, the pads are vertically juxtaposed and the letter A straddles their common boundary.

Many other configurations could be imagined, optionally comprising more than two pads. All the characters, figures or letters, could also be subjected to encoding with a single pad.

Any code other than ASCII decimal could be used, for example, ASCII hexadecimal.

It will be immediately apparent to the person skilled in the art that the effectiveness of the optical encoding set out by the present invention is superior in several regards to that of a current device for recognising characters which could itself carry out automatic reading of texts. Firstly, encoding with pads, advantageously coloured pads, ensures redundancy of the information recorded which allows a text encoded in this manner to be read, even when damage to the surface of the strip (such as scratches, abrasions, tears or contamination) would make it difficult or impossible to read some characters. Furthermore, the surface occupied by a coloured pad may be much greater than that of the associated character. The signal/noise ratio of the reading of the optical encoding is far superior to that found with reading by character recognition. Finally, automatic reading of an optical code in colour is faster than that carried out by recognition of the shape of a character, which uses complex algorithms.

As will be seen below, particularly in conjunction with FIGS. 8 and 9, the optical encoding according to the invention not only allows automatic reading of archived documents of the “text” type to be carried out but also allows automatic reading of directories allowing recordings or parts of recordings of interest to be located on the strip. Such directories must not only contain the positions of the recordings carried by the strip but also the types of the documentary objects recorded. According to the invention, those types are codified by numbers and are particularly involved in the construction of the data processing file used in order to expose a strip of photosensitive film to the images of the various recordings which that strip will have to carry after development.

Merely by way of non-limiting example, that codification may be in the following form:

0xx=Control objects
000=zero or section end
01x=Definition of formatting (sectors and tracks)
   011=Page Mode
   012=Strip Mode
02x=sub-directory
   021=level 1
   022=level 2
03x=Definition of special formats
1xx=IMAGE type objects
11x=photographic IMAGE
12x=drawing IMAGE
   120=whole drawing
   125=segmented drawing
13x=text IMAGE
   130=text only
   132=text+inset

2xx=mono-dimensional type objects
21x=mono-channel SOUND
22x=multi-channel SOUND
   225=5.1 SOUND
23x=sensor SIGNALS

3xx=TEXT type object
300=ASCII text

4xx=MULTIMEDIA type object
41x=simple resolution video (SD)
   411=SD 50 Hz
   412=SD 60 Hz
43x=high resolution video (HD)

45x=PC video format
451=progressive VGA video format (320×240 pixels)
452=progressive VGA video format (640×480 pixels)

Such codification allows documentary objects of very different types and sizes to be recorded on the same strip with flexibility.

The term “strip mode” is intended to refer to formatting of the strip into parallel tracks (for example, 3 tracks) in accordance with the length of the strip. Such formatting is advantageous for temporal objects, such as videograms, associated with sounds. Each track corresponds to a temporal object and therefore comprises an “image” sub-track and one or more “sound” sub-tracks.

The term “page mode” is intended to refer to formatting of the strip as in that illustrated in FIG. 1 of the appended drawings. It is particularly advantageous for objects such as texts, drawings, etc., or videograms when the dimensions of the image (or of the videogram) are equal to or similar to those of a sector or when the image has to be spread over several consecutive sectors owing to its large dimensions.

This page mode may also be advantageous for groups of videograms when the size thereof is broadly less than that of a sector. An object formatted in this manner will be described below in conjunction with FIGS. 5 and 7.

According to an advantageous feature of the recording method according to the present invention, the formatting of the film strip is adapted to the type of object recorded. This type and adapted format are recorded during the constitution of the generic data processing file set out above in directories which are also recorded on the strip.

Such a directory may be intended only for visual reading or only for automatic reading. Advantageously, it makes use of the optical encoding described above in conjunction with the FIGS. 2 to 4D in order to provide two possible methods of reading this directory, visual and automatic.

Reference is made to FIG. 8 of the appended drawings to describe in greater detail such a directory with double-reading. It is configured to be recorded on a sector of the strip. This may be a main directory or a sub-directory which is positioned on a sector located downstream of the sector comprising the main directory. Its position is listed in the main directory.

This directory comprises a plurality of lines, only the first and the last of which have been illustrated for the sake of the clarity of the Figure, and a plurality of columns referred to as No., type, name, sector, Nb (number), param (parameter) 1 and 2.

Each line contains characters which are superimposed on pads, advantageously in colour, constituting a translation of those characters in accordance with the encoding described above in conjunction with FIGS. 2 to 4D, with the exception of the “name” column which is encoded in ASCII decimal. The figures are superimposed on the corresponding coloured pads. The letters are superimposed on the corresponding pairs of pads in accordance with the format defined by FIG. 4B.

Both the characters and their optical encoding can be read visually. Ambiguity concerning the shape of a typographic character can be removed by decoding its encoding in coloured pads. In this manner, the present invention provides improved security during transmission of information.

The directory of FIG. 8 can be read, visually or automatically, as follows:
line or entry No. 01: this is an object of the type 411 (video 50 Hz, “standard definition” according to standard “COIR-601”) which is named SCENE 01, this scene beginning at sector 10 and extending over 58 sectors, which scene does not have any additional parameters.

Those additional parameters serve to complement the definition of some objects. For example, the parameters 1 and 2 may be start and end dates for temporal objects, respectively. Other types of parameter are possible, as will be seen below. Their meanings are set out in the leading portions.
Entry No. 02: again this is an object of the type 411 which is named SCENE 02, beginning at sector 69 and extending over 29 sectors, without any additional parameters.
Entries No. 03 to 20: not developed for the sake of clarity of the Figure, but containing information for reading similar to that set out in detail above.
Entry No. 20: this is an object of the type 300 (pure text in ASCII) named EDL (Edition Decision List, that is, list of extracts for assembly as is known to the person skilled in the art), that object which extends over 6 sectors from sector 251 not having any additional parameters.
Entry No. 21: this is an object of the type 000, denoting the end of the directory, as was seen above.

It was also set out above that the present invention allows adaptation of the format of the sectors to the type of documentary object to be recorded on those sectors, and not the objects to the format of the sectors, as is generally the rule for storing data on conventional data processing media. This is an advantageous feature of the recording method according to the present invention because it allows the format to be provided with a dimension allowing human reading of the object recorded on a sector of that format.

Since objects of different types can be recorded on the strip consecutively one after the other, it is advantageous for the transition from one format to the next to be duly recorded in the numerical file which is the basis for preparing a strip according to the invention. There is set out below, purely by way of illustration, an example of an intermediate directory organising such a transition:

| N° | TYPE | NAME | SECTOR | Nb sector | Param 1 | Param 2 |
|---|---|---|---|---|---|---|
| 10 | 0011 | Page mode | 0129 | 00 | 2048 | 1536 |
| 11 | 0130 | Context 01 | 0129 | 02 | 0000 | 0000 |
| 12 | 0011 | Page mode | 0131 | 00 | 2048 | 3072 |
| 13 | 0120 | Logo drawing | 0131 | 02 | 0000 | 0000 |
| 14 | 0012 | Strip mode | 0133 | 00 | 0303 | 0000 |
| 15 | 0411 | SCENE 01 | 0133 | 80 | 0000 | 0000 |

This directory indicates, at line 10, that the strip is moving in the page mode to sector 129 and that the resolution of the page is 2048×1536 pixels, which corresponds precisely to a basic sector, as was seen above.

Line 11 indicates that it is a text in the form of an image, such as current microfilm, for example, occupying two sectors, that is to say, as many as two pages of text.

Line 12 sets out a new definition of a page, this time over two sectors which gives a resolution of 2048×3072 pixels.

Line 13 defines the object recorded as being a whole drawing.

Line 14 imposes a strip mode from sector 0133, having three image tracks and three sound tracks (parameter 0303).

Line 15 sets out the name (SCENE 01), the type (411) and the maximum length of the object. This occupies 80 sectors, that is to say, 80×4=320 perforations. If this object must be skipped, 320 perforations have to be travelled to arrive at the following object.

It will be understood that the recording method according to the invention thus allows archiving, on the same recording medium, of documentary objects of very different types. It is thereby possible, for example, to combine on the same medium documentary objects which are heteroclitic but which all relate to the same subject, the medium constituting a complete dossier on this subject. Complications which are connected with the administration of a set of recording media of different types are thereby avoided. Furthermore, the dossier constituted in this manner is organised in accordance with a logic which remains accessible in the long term.

Reference is again made to FIG. 1 of the appended drawings to complement the description which has been made of a specific embodiment of a recording medium obtained by the recording method described above, this embodiment merely being given by way of non-limiting example.

For simplicity, there will only be set out a description of a film strip carrying a single recording of the type 451 defined above, that is to say, a video recording in progressive CGA format having a resolution of 320×240 pixels.

In this particular case, the title page recorded in the sector 1a of the leading portion of the strip indicates in an uncoded manner, if it is a broadcast, the date thereof and the subject(s) of this broadcast.

The nomenclature recorded on the sector 1b contains, in addition to the characteristics of the encoding with coloured pads set out above in conjunction with FIGS. 2 and 3, the necessary characteristics of a recording of the type 451, that is to say that it is a sequence of computer videograms having a spatial resolution of 320×240 pixels, the colour red, green or blue, being resolved at 256 levels. The sound is monochannel, sampled 8000 times per second.

A sector of the strip, corresponding to a matrix of 2048×1536 pixels, carries 36 videograms and the recording of the corresponding sound. The nomenclature is complemented by a schematic illustration RS, intended for intuitive reading, of such a sector of the strip. That schematic illustration RS may be included on the sector 1b or on an adjacent sector such as the sector 1d, as illustrated in FIG. 1.

Reference is made to FIG. 5 of the appended drawings to describe in greater detail that schematic illustration RS. There are apparent therein pictograms L1, L2 and L3 representing in a stylised manner an eye, an ear and a clock face, respectively. The pictograms L1, L2 and L3 are provided so as to allow intuitive reference to the portions of a sector of the strip carrying a portion of the content of the recording, which portions correspond to the recording of the image portion, recording of the sound and the start point of those two recordings in synchronism, respectively. The image portion contains a rectangular mosaic having 6×6 elementary fields Vij (with i and j being from 1 to 6), that is, 36 fields. The positions of those fields correspond to those of the videograms carried by a standard sector 1i of the strip, as schematically shown by way of illustration in FIG. 7. In the drawing of FIG. 5, arrows indicate the order in which the videograms of such a sector follow each other over time.

It will be noted that the videograms are recorded in Page Mode. In a variant, they could be recorded in Strip Mode. In this instance, the drawing of FIG. 5 would be different.

It is clear that the information that the archivist of the future can intuitively draw from the analysis of the sectors of the leading portion of the strip, in particular sector 1d, are sufficient to write software for processing the output signals of the scanner with which it is associated to bring about automatic reading of the video program, of the type 451, recorded on a succession of sectors of the strip arranged after the leading portion illustrated in FIG. 1.

That succession of sectors, which carries the content itself of the video programme, is immediately preceded by a sector (not illustrated) which carries a cross conventionally indicating the start point of the recording of this programme and followed by another cross (not illustrated), indicating the end thereof.

According to the present invention and as is visible on the sector 1e of the leading portion of the strip illustrated in FIG. 1, the recording is also advantageously preceded by a preview AP of the content of this recording and a directory R of the scenes which follow each other in the video programme. This preview and this directory are illustrated in greater detail in FIGS. 6 and 9, respectively.

The preview AP is constituted by a mosaic of elementary images, each one representing one of the successive scenes of this programme. The presence of this preview, intended purely for visual reading, constitutes an aid to evaluation of the interest of the programme by an archivist who must decide, for example, if that interest is sufficient to justify the creation of software necessary to allow automatic reading thereof. The creative effort can therefore be limited to the creation of the software for reading a portion of interest PI of the archive. That contributes to optimising the use of the money available to exploit the archive.

Each elementary image comprises, as a superimposition, an inscription (not illustrated for the sake of clarity of the Figure) setting up a logical connection to the corresponding line of the directory R which will now be described in conjunction with FIG. 9.

The directory R of FIG. 9 has the same format as that of FIG. 8 described above, and has column titles that are identical to those of FIG. 8. The successive lines or entries thereof provide the characteristics of the successive scenes of the video programme, of which FIG. 6 sets out a preview AP. In this manner, for example, the entry 01 indicates that the scene 01 is of the type 451 and that it is recorded on three sectors starting from sector 01. Similarly, the scene 02 begins at sector 04 and extends over 20 sectors, etc.

Advantageously, the directory of FIG. 9 similarly to that of FIG. 8 is doubled by a subjacent layer of coloured pads which constitutes the translation thereof intended for automatic reading according to the present invention. That layer is not illustrated for the sake of clarity of FIG. 9. The possible double reading, human or automatic, of this directory ensures the utility thereof both before and after the software necessary for automatic reading has been created.

In a variant, the elementary images of the preview of FIG. 6 could be integrated, line by line, into the directory of FIG. 9. The preview may then be omitted from the leading portions of the strip.

It now appears that the present invention allows the objects set out to be favourably achieved, that is to say, providing a method for recording data, particularly but not exclusively audiovisual data, on a recording medium which is capable of constituting an archive which can be exploited automatically, even over a very long term, in spite of the disappearance of the data processing means, hardware and/or software, which were available at the time of its creation. This medium, which is optical, is robust. The recording method ensures both intuitive human reading and automation of the reading of the original data. It organises the classification of the data recorded on the medium. It further incorporates in the medium means for repairing damage or modifications which may be suffered by the medium.

The present invention ensures the long-term conservation of all types of recording and in particular recordings of digital origin, such as, for example, the video recording in the CGA format incorporated in the specific embodiment of the recording medium described above, avoiding the disadvantages connected with the short useful life of current digital recording media.

In this manner, by means of the invention, the conservation of access to the stored digital data no longer requires maintenance of outdated systems or expensive migration of data from a system which is becoming obsolete to a more recent system, those migration operations further involving losses of information.

Similarly, the invention ensures direct access to the content of a recording medium, before any attempt at automatic reading, with automatic reading only being carried out advisedly. The hardware and software used to this end benefit from the prior art at the reading date of the recording medium.

Naturally, the invention is not limited to the embodiment described and illustrated, which has been given merely by way of example. In this manner, it obviously extends to the recording and reading of data relating to documentary objects other than those of the type 451 set out above, and in particular the other documentary objects listed above. The person skilled in the art will readily be able to apply the principles of the invention set out above to the recording and re-reading of those other objects in the long term.

Similarly, the invention is not limited to the production of a strip-like recording medium. In this manner, that “recording medium” can be constituted by a single strip or sheet, as in a collection of such sheets or strips which are assembled in installments, modules or other containers so as to form a unit.

1-29. (canceled)

30. Data recording method for the automatic long-term reading of those data, wherein there is recorded on the same recording medium:
a) an encoded recording (A) of the data allowing them to be read automatically,
b) a recording (B), intended for intuitive visual reading, of the knowledge necessary for using means for decoding the data in order to read them automatically.

31. Method according to claim 30, wherein the intuitive reading is brought about by the juxtaposition, on the recording medium, of visual reading signs and the associated codes thereof.

32. Method according to claim 31, wherein the codes are intended for automatic reading by optical means.

33. Method according to claim 32, wherein the code associated with the sign is constituted by at least one elementary field of a recording surface of the medium having an optical characteristic specific to the sign.

34. Method according to claim 33, wherein the code associated with the sign is constituted by combining a plurality of elementary fields of the medium, for which a combination of the optical characteristics is specific to the sign.

35. Method according to claim 33, wherein the characteristic is selected from the group formed by: a shape, colour and/or optical density of at least one field of the recording medium.

36. Method according to any one of claim 33, wherein the sign associated with each of the codes is adjacent to the code.

37. Method according to either claim 34, wherein the sign associated with each of the codes is superimposed on the code.

38. Method according to claim 31, wherein the recording medium is formatted in consecutive sectors.

39. Method according to claim 38, suitable for recording on the medium documentary objects of different types, wherein the sectors are configured in accordance with the type of each object.

40. Method according to claim 39, wherein, for each object recorded, a directory of the sectors on which it is recorded is further recorded.

41. Method according to claim 40, wherein the directory is intended to be read visually.

42. Method according to claim 41, wherein the directory (R) is further intended to be read automatically.

43. Method according to claim 38, wherein there is further recorded, for each documentary object recorded, a visually readable nomenclature of the information to be taken into consideration in order to prepare automatic reading of the recording.

44. Method according to claim 43, wherein the nomenclature includes the rules of the encoding of signs.

45. Method according to claim 44, wherein the
nomenclature comprises a schematic illustration of the distribution of the data relating to at least one of the objects on a standard sector of the medium.

46. Method according to claim 45, wherein the nomenclature comprises pictograms in order to assist visual recognition of various portions of a recording of an object comprising recordings of different types.

47. Method according to 30, wherein there is further recorded on the medium a visually readable preview of characteristics of the data intended for automatic reading, which preview is capable of allowing preselection of a portion of interest of the recording (A).

48. Method according to claim 47, wherein, for each object recorded, a directory of the sectors on which it is recorded is further recorded, and wherein the preview is integrated in the directory.

49. Data recording medium obtained by the method according to claim 30, comprising:
a) an encoded recording (A) of the data allowing them to be read automatically,
b) a recording (B), intended for intuitive visual reading, of the knowledge necessary for using means for decoding the data in order to read them automatically.

50. Data recording medium according to claim 49, wherein the recordings (A) and (B) are carried by a layer of an optically readable recording material.

51. Data recording medium according to claim 50, wherein the medium is in the form of a sheet-like product.

52. Data recording medium according to claim 50, wherein the medium is in the form of a strip-like product.

53. Data recording medium according to claim 52, wherein the medium is formatted in consecutive sectors along the longitudinal axis of the strip.

54. Data recording medium according to claim 53, comprising, at least at one end of the strip, visually readable sectors which are assigned to recording characteristics of the content of the automatically readable encoded data, those encoded data being recorded on sectors of the strip associated with the visually readable sectors.

55. Data recording medium according to claim 54, wherein the visually readable sectors comprise sectors which are assigned to recording a nomenclature of the information to be taken into consideration in order to prepare automatic reading of the encoded recording (A) of the data.

56. Data recording according to either claim 54, wherein the visually readable sectors are repeated at the other end of the strip.

57. Data recording medium according to claim 53, comprising recordings of a plurality of documentary objects of different types, wherein the various successive lengths of the strip which carry those recordings are formatted in sectors having dimensions adapted to the type of the corresponding recording.

58. Data recording medium according to claim 49, comprising recordings of data intended to be used during operations for restoring/repairing that medium.
